(19) United States
(12) Patent Application Publication
(10) Pub. No.: US 2018/0272795 A1
(43) Pub. Date: Sep. 27, 2018

(54) ELECTRONIC DEVICE AND COVER THEREOF

(71) Applicant: ASUSTeK COMPUTER INC., TAIPEI (TW)

(72) Inventor: Bin-Yi LIN, Taipei (TW)

(21) Appl. No.: 15/861,812

(22) Filed: Jan. 4, 2018

(30) Foreign Application Priority Data
Mar. 27, 2017 (TW) 106110188

(51) Int. Cl. B44C 3/02; G02B 3/08; B29D 11/00; G06F 1/16; B44C 1/18; B44C 3/04

(52) U.S. Cl. CPC B44C 3/025; G02B 3/08; B29D 11/00269; H05K 5/0086; B44C 1/18; B44C 3/04; G06F 1/1637

(57) ABSTRACT

An electronic device comprises a cover and an outer casing. The cover includes a first light transmitting substrate layer and a first pattern layer. The first pattern layer is attached to bottom of the first light transmitting substrate layer and includes a plurality of first microstructure patterns. The outer casing is mounted on the cover. The outer casing includes a second light transmitting protection layer and a second pattern layer. The second light transmitting protection layer includes a first surface facing the cover. The second pattern layer is configured at the first surface of the second light transmitting protection layer. The second pattern layer includes a plurality of second microstructure patterns. The first pattern layer and the second pattern layer are superimposed to form a virtual pattern image.

### CROSS-REFERENCE TO RELATED APPLICATION

This application claims the priority benefit of Taiwan application serial No. 106110188, filed on Mar. 27, 2017. The entirety of the above-mentioned patent application is hereby incorporated by reference herein and made a part of specification.

### BACKGROUND OF THE INVENTION

### Field of the Invention

The invention relates to a cover and, more particularly, to a cover of an electronic device.

### Description of the Related Art

Users are usually attracted by the outlook of electronic devices such as mobile phones, notebook computers and tablet PCs. Therefore, the casings of the electronic devices with three-dimensional relief, hair pattern, and transferred patterns are become popular in recent years.

### BRIEF SUMMARY OF THE INVENTION

According to a first aspect of the disclosure, an electronic device is disclosed. The electronic device, comprising: a cover, including: a first light transmitting substrate layer; and a first pattern layer, attached to a bottom of the first light transmitting substrate layer and including a plurality of first microstructure patterns; and an outer casing, mounted on the cover, the outer casing includes: a second light transmitting protection layer, including a first surface facing the cover; and a second pattern layer, configured at the first surface of the second light transmitting protection layer and including a plurality of second microstructure patterns, wherein the first pattern layer and the second pattern layer are superimposed to form a virtual pattern image.

According to a second aspect of the disclosure, a cover is disclosed. The cover, applied to an electronic device, comprising: a first light transmitting substrate layer; a first pattern layer, attached on the first light transmitting substrate layer and including a plurality of first microstructure patterns, wherein the first pattern layer has a first refractive index; a first light transmitting ink layer, configured above the first pattern layer; a second pattern layer, attached to a bottom of the first light transmitting substrate layer and including a plurality of second microstructure patterns, wherein the second pattern layer has a second refractive index, and the first refractive index is different from the second refractive index; and a plating layer, configured under the second pattern layer; a printing layer, configured under the plating layer and having a background color.

According to a third aspect of the disclosure, a cover is disclosed. The cover, applied to an electronic device, comprising: a first light transmitting substrate layer; a first pattern layer, attached on the first light transmitting substrate layer and including a plurality of first microstructure patterns; a first light transmitting ink layer, configured above the first light transmitting substrate layer and having a fifth refractive index; a second light transmitting ink layer, configured above the first light transmitting ink layer and having a sixth refractive index, wherein the fifth refractive index is different from the sixth refractive index; and a second pattern layer, configured above the second light transmitting ink layer and including a plurality of second microstructure patterns.

### BRIEF DESCRIPTION OF THE DRAWINGS

FIG. 1 is a schematic diagram showing a cover and an outer casing of an electronic device in an embodiment;

FIG. 2 is a schematic diagram showing a cover and an outer casing of an electronic device in an embodiment;

FIG. 3 is a schematic diagram showing a cover and an outer casing of an electronic device in an embodiment;

FIG. 4 is a schematic diagram showing a cover in an embodiment;

FIG. 5 is a schematic diagram showing a cover in an embodiment;

FIG. 6 is a schematic diagram showing a cover in an embodiment;

FIG. 7 is a schematic diagram showing a cover in an embodiment;

### DETAILED DESCRIPTION OF THE EMBODIMENTS

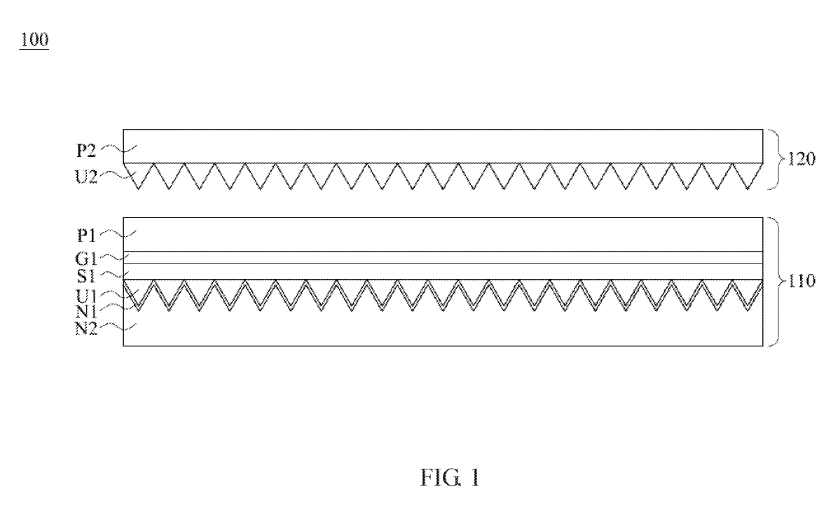

Please refer to FIG. 1. FIG. 1 is a schematic diagram showing a cover 110 and an outer casing 120 of an electronic device 100 in an embodiment. The electronic device 100 is a mobile phone, a notebook computer, or a tablet computer, which is not limited herein. The cover 110 is mounted on the electronic device 100 to protect the mainboard and other components inside the electronic device 100. In an embodiment, the cover 110 is a battery cover of the electronic device 100. In an embodiment, the outer casing 120 is a protective casing selectively mounted at the outer of the cover 110 of the electronic device 100 for further protection.

In FIG. 1, the cover 110 of the electronic device 100 includes a first light transmitting protection layer P1, an adhesive layer G1, a first light transmitting substrate layer S1, a first pattern layer U1 and a plating layer N1 that layered in order from outside to inside. In an embodiment, the material of the first light transmitting substrate layer S1 includes polyethylene terephthalate (PET). The first pattern layer U1 is made of UV glue in an embodiment. In the manufacturing process of an embodiment, the first light transmitting protection layer P1 is first provided. The first light transmitting protection layer P1 is adhered to the first light transmitting substrate layer S1 via the adhesive layer G1. Then, the UV glue (such as UV ultraviolet Rubber) is coated on one side of the first light transmitting substrate layer S1. The microstructure patterns are formed by suppressing, cutting or etching the UV glue on the first light transmitting substrate layer S1. Then, the first pattern layer U1 is formed by irradiating the ultraviolet light to the microstructure patterns. Therefore, the first pattern layer U1 is attached to the first light transmitting substrate layer S1. The zigzag pattern of the pattern layer presented in figures is used to indicate a three-dimensional structure, and the actual shape is not limited herein.

Practically, the first pattern layer U1 includes a plurality of first microstructure patterns, such as a lenticular type, a micro-lens type, a V-cut type or a Fresnel-lens type, which is not limited herein. Visual effects are changed by refraction, reflection, and diffusion of the light between the adjacent first microstructure patterns. In the embodiment, the distance between the adjacent first microstructure patterns is a first distance d1.

After the first pattern layer U1 is formed, the first pattern layer U1 is selectively plated to form the plating layer N1 to further protect the first pattern layer U1. Then, the damage and deformation of the first pattern layer U1 due to an external force would be avoided when. In an embodiment, the plating layer N1 is formed by a non-conductive vacuum metallization (NCVM) technique to improve the metallic feeling in visual. A printing layer N2 is provided under the plating layer N1. In an embodiment, the printing layer N2 is doped with a background color to make the cover 110 show various colors according to requirements. The printing layer N2 is opaque and therefore is configured at a side facing the inside of the electronic device 100.

The first light transmitting protection layer P1 provides further hardening and protection for the outer of the cover 110. Consequently, the cover 110 is not easily bent, worn or scratched. Since the first light transmitting protection layer P1, the adhesive layer G1 and the first light transmitting substrate layer S1 are light-transmitting material, the light can reach the first pattern layer U1 after passing through the first light transmitting protection layer P1, the adhesive layer G1 and the first light transmitting substrate layer S1. Then, the appearance of the product shows the texture patterns provided by the first pattern layer U1.

The outer casing 120 includes a second light transmitting protection layer P2 and a second pattern layer U2. The material of the second light transmitting protection layer P2 is similar to that of the first light transmitting protection layer P1, such as transparent plastic or glass. The second light transmitting protection layer P2 has a first surface facing the cover 110 (the lower surface of the second light transmitting protection layer P2 shown in the FIG. 1). In the embodiment, the UV glue coated on the first surface of the second light transmitting protection layer P2 is processed to form the second pattern layer U2. That is, the second light transmitting protection layer P2 is used as a substrate of the second pattern layer U2. Similar to the first pattern layer U1, the second pattern layer U2 also has a plurality of second microstructure patterns. The distance between the adjacent second microstructure patterns of the second pattern layer U2 is a second distance d2.

In an embodiment, the second microstructure patterns of the second pattern layer U2 and the first microstructure patterns of the first pattern layer U1 are different microstructure pattern types. In another embodiment, the second pattern layer U2 has the same microstructure patterns as that of the first pattern layer U1 (such as the Micro-lens type).

The second distance d2 between the adjacent second microstructure patterns is the same or different from the first distance d1 between the adjacent first microstructure patterns to show various visual effects. In an embodiment, the first distance d1 is different from the second distance d2. Then, the optical characteristics of the first pattern layer U1 are different from these of the second pattern layer U2.

The first pattern layer U1 has a first refractive index, and the second pattern layer U2 has a second refractive index. Since the kind and amount of the additives added into the UV glues of the first pattern layer U1 and the second pattern layer U2 are different, the first refractive index is different from the second refractive index. For example, an oligomer, such as a resin, an initiator, a stabilizer, or the like is added into the UV glue to form the first pattern layer U1 or the second pattern layer U2 with different refractive indices or different translucent degrees. In an embodiment, the optical characteristics of the first pattern layer U1 are different from the optical characteristics of the second pattern layer U2 due to the difference between the first refractive index and the second refractive index.

When the outer casing 120 is mounted on the cover 110, the light is transmitted from the second light transmitting protection layer P2 of the outer casing 120 to the second pattern layer U2, and further transmitted to the first light transmitting protection layer P1, the adhesive layer G1, a first light transmitting substrate layer S1, a first pattern layer U1, a plating layer N1, and a printing layer N2 of the cover 110. Therefore, the image of the first pattern layer U1 and the image of the second pattern layer U2 are superimposed. Virtual pattern images for visual effect are presented via optical refraction, reflection, diffusion.

By varying the density (relating to the first distance d1 and the second distance d2), the degree of undulation (concavity and convexity), or the inclination angle (the angle between patterns and the flat surface of the cover 110 or the angle between patterns and the flat surface of the outer casing 120) of the microstructure patterns of the first pattern layer U1 and the microstructure patterns of the second pattern layer U2, various virtual images are presented. Thus, the various visual effects are showed by combining the covers 110 and outer casings 120 with microstructure patterns of different densities, undulation or inclination angles.

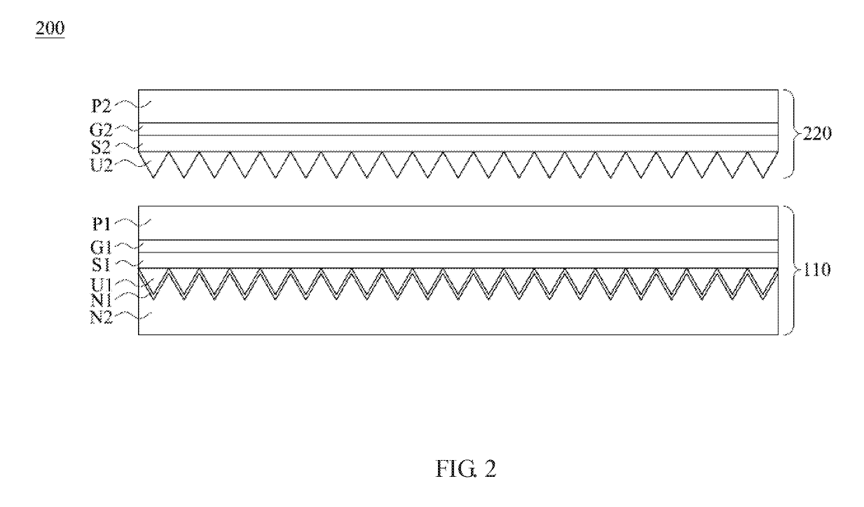

In an embodiment, the outer casing 120 is provided with a base layer. FIG. 2 is a schematic diagram showing a cover 110 and an outer casing 220 of an electronic device 200 in an embodiment. The cover 110 of the electronic device 200 is the same as the cover 110 of the electronic device 100. The detailed structure is described in the above paragraph and not described again. In comparison with the outer casing 120 of the electronic device 100, the outer casing 220 is further provided with a second light transmitting substrate layer S2. The second light transmitting substrate layer S2 is similar to the first light transmitting substrate layer S1. In an embodiment, the second light transmitting substrate layer S2 is also made of PET material.

In the manufacturing process, the first surface (the lower surface of the second light transmitting protection layer P2 shown in FIG. 2) of the second light transmitting protection layer P2 is adhered to one side of the second light transmitting substrate layer S2 via an adhesive layer G2. Then, the other side of the second light transmitting substrate layer S2 is coated with UV glue, and the second pattern layer U2 is formed via the UV glue. That is, the second light transmitting substrate layer S2 serves as a substrate for the second pattern layer U2.

The second light transmitting protection layer P2 is used to protect the second light transmitting substrate layer S2 and the second pattern layer U2. Similarly, a virtual pattern image on the surface of the electronic device 200 is formed when light passes through the second light transmitting substrate layer S2, and the virtual pattern image is configured by superimposing the patterns of the first pattern layer U1 and the second pattern layer U2.

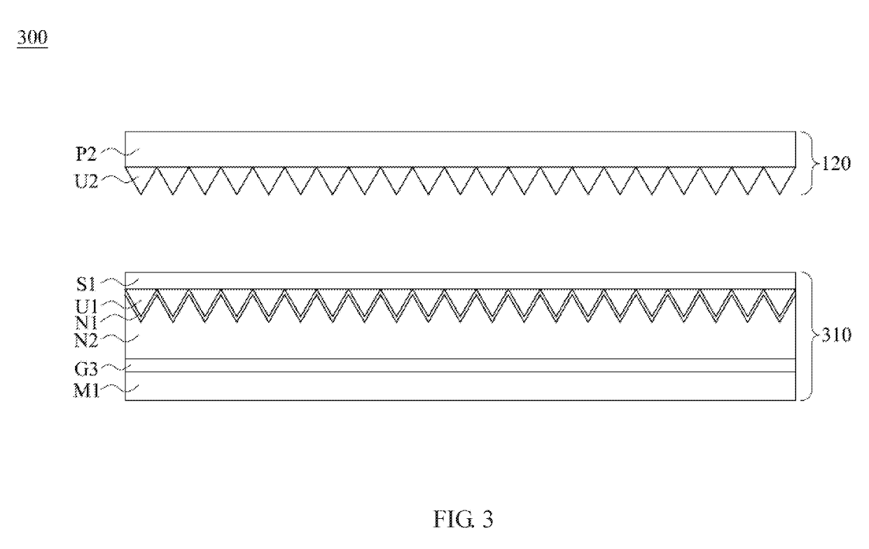

In an embodiment, the first light transmitting protection layer P1 of the cover 110 is made of a lightproof hard material. The cover 310 and the outer casing 120 of the electronic device 300 are described with reference to FIG. 3. The outer casing 120 of the electronic device 300 is same to the outer casing 120 of the electronic device 100, which is not described again for concise.

Similar to the cover 110, the cover 310 includes the first light transmitting substrate layer S1, the first pattern layer U1, the plating layer N1 and the printing layer N2. However, the cover 310 does not include the first light transmitting protection layer P1, but includes a base layer M1. The base layer M1 is adhered to the printing layer N2 through the adhesive layer G3. Since the base layer M1 is configured at the bottom, it does not affect the appearance of the image of the first pattern layer U1 on the surface. Thus, the base layer M1 can be made of any transparent or opaque material such as glass, plastic, metal, or the like. The base layer M1 supports the printing layer N2, the plating layer N1, the first light transmitting substrate layer S1 and the first pattern layer U1 thereon. Therefore, similar to the protection of the first light transmitting protection layer P1, with the base layer M1, the cover 310 is stronger and not easily bent by an external force.

In an embodiment, the outer casing and the cover of the electronic device are integrally formed. For example, the outer casing of each electronic device in FIG. 1 to FIG. 3 is directly adhered to the cover via an adhesive, or a process is used to combine the outer casing and the cover.

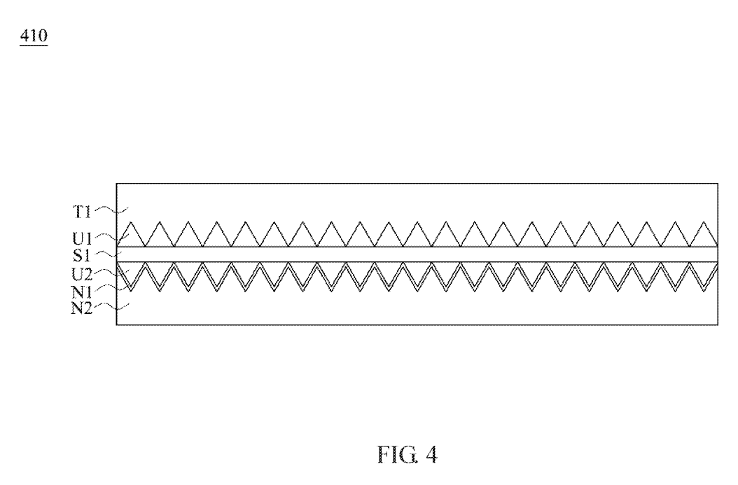

In an embodiment, virtual pattern image is presented at the cover. FIG. 4 is a schematic diagram showing the cover 410 in an embodiment. The cover 410 is used at an electronic device, such as a mobile phone, a notebook computer, a tablet computer. The cover 410 includes a first light transmitting ink layer T1, a first pattern layer U1, a first light transmitting substrate layer S1, a second pattern layer U2, a plating layer N1 and a printing layer N2 from top to bottom.

In manufacture, the UV glue is coated on both sides of the first light transmitting substrate layer S1 and processed to form a first pattern layer U1 and a second pattern layer U2 with microstructure patterns. In an embodiment, the first microstructure patterns of the first pattern layer U1 and the second microstructure patterns of the second pattern layer U2 have the same type, such as a lenticular type, a micro-lens type, a V-cut type or a Fresnel type. In manufacture, in an embodiment, the first light transmitting ink layer T1 is formed above the surface of the first pattern layer U1 via evaporation. Next, the plating layer N1 is selectively plated on the second pattern layer U2. Then, a printing layer N2 is formed on the surface of the plating layer N1. The printing layer N2 has a background color.

Except for by adjusting parameters (distances described above, concavity and convexity and so on) of the microstructure patterns of the first pattern layer U1 and the second pattern layer U2, the virtual image also can be changed by changing the refractive index of the material of layers.

For example, in the embodiment of FIG. 4, the first pattern layer U1 has a first refractive index, and the second pattern layer U2 has a second refractive index. The first refractive index and the second refractive index are different depending on the kind and amount of the additive added into the UV glue. For example, an oligomer such as a resin, an initiator, a stabilizer, or the like is added into the UV glue to make the first pattern layer U1 or the second pattern layer U2 to cause the difference of refractive indices or different translucent degrees of the first pattern layer U1 or the second pattern layer U2.

Since the cover 410 has the first pattern layer U1 and the second pattern layer U2, the images of the first pattern layer U1 and the second pattern layer U2 are superimposed to form virtual pattern images.

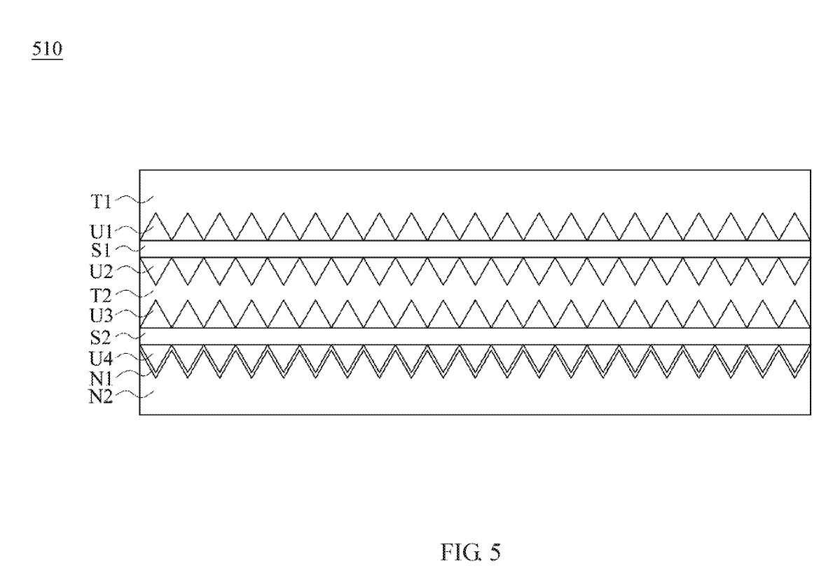

In an embodiment, more pattern layers are formed at the cover to form a virtual image with multi-layered effect. Compared to the cover 410, the cover 510 in FIG. 5 includes a second light transmitting ink layer T2, a third pattern layer U3, a second light transmitting substrate layer S2, a fourth pattern layer U4 under the second pattern layer U2.

In an embodiment, the third pattern layer U3 also has the same type of microstructure patterns and has a third refractive index. The fourth pattern layer U4 also has the same type of microstructure patterns and has a fourth refractive index. The third refractive index and the fourth refractive index are various depending on the material of the third pattern layer U3 and the fourth pattern layer U4. The third pattern layer U3 and the fourth pattern layer U4 are attached to two sides of the second light transmitting substrate layer S2, respectively. Similarly, the bottom of the fourth pattern layer U4 has a plating treatment to form the plating layer N1. A printing layer N2 is formed on the surface of the plating layer N1. The second light transmitting ink layer T2 is used to combine the second pattern layer U2 and the third pattern layer U3. As a result, a quadruple virtual image is presented at the cover 510 via the first pattern layer U1, the second pattern layer U2, the third pattern layer U3, and the fourth pattern layer U4.

In an embodiment, more pattern layers are added to the cover 510 to form more complex optical effects. The number of pattern layers can be changed according to requirements, which is not limited herein.

In the embodiment of FIG. 5, in addition to that the first pattern layer U1, the second pattern layer U2, the third pattern layer U3, and the fourth pattern layer U4 has different refractive indices, respectively, the refractive index of the light transmitting ink layers also can be changed by adding dopants. In an embodiment, the first light transmitting ink layer T1 has a fifth refractive index, and the second light transmitting ink layer T2 has a sixth refractive index. The fifth refractive index of the first light transmitting ink layer T1 is different from the sixth refractive index of the second light transmitting ink layer T2, which makes the cover 510 have more complex optical effects.

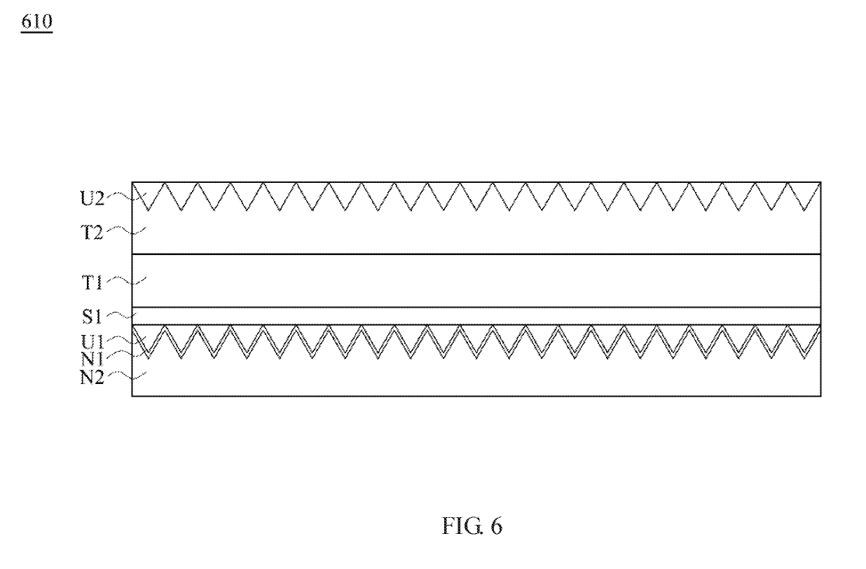

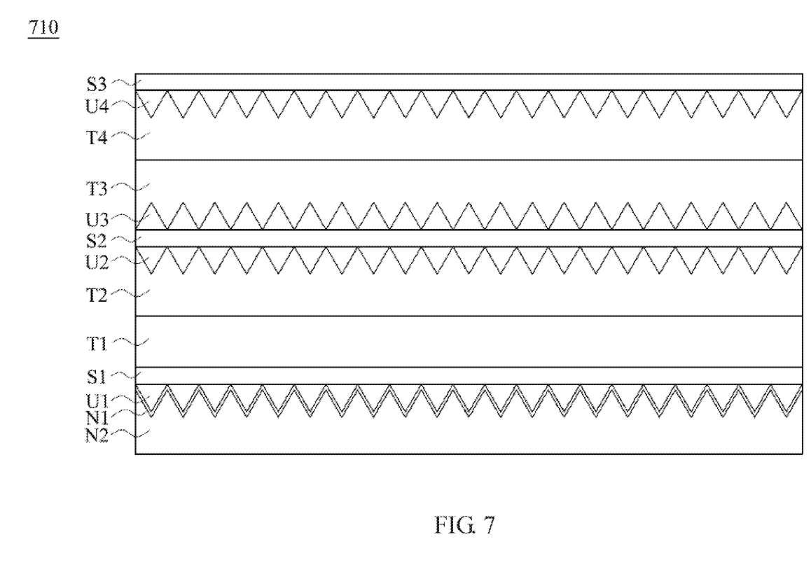

Besides that the refractive index of the UV glue can be changed via adding dopant, the refractive index of the light-permeable ink layer can also be changed by adding dopants, as such as the implementation shown in FIG. 6 and FIG. 7.

FIG. 6 is a schematic diagram illustrating a cover 610 in an embodiment. The cover 610 has a second pattern layer U2, a second light transmitting ink layer T2, a first light transmitting ink layer T1, a first light transmitting substrate layer S1, a first pattern layer U1, and a plating layer N1 from top to bottom. In an embodiment, the first pattern layer U1 and the second pattern layer U2 have the same type of microstructure patterns. The first light transmitting ink layer T1 is coated on the first light transmitting substrate layer S1, and the second light transmitting ink layer T2 is further coated on the first light transmitting ink layer T1. In addition, the second pattern layer U2 is configured above the second light transmitting ink layer T2. The first pattern layer U1 is attached to the bottom of the first light transmitting substrate layer S1. The plating layer N1 is selectively plated to protect the first pattern layer U1. Then, the printing layer N2 is formed under the first pattern layer U1 and the plating layer N1.

The first light transmitting ink layer T1 and the second light transmitting ink layer T2 have the same or different refractive indices. A virtual pattern image is presented after light passes through the second pattern layer U2, the second light transmitting ink layer T2, the first light transmitting ink layer T1, and the first pattern layer U1.

In an embodiment, when the first light transmitting ink layer T1 and the second light transmitting ink layer T2 have different refractive indices, the first pattern layer U1 and the second pattern layer U2 in FIG. 6 also have different refractive indices. Therefore, the cover 610 has a more rich optical effect.

In an embodiment, the cover 610 has more layers structure, as shown in FIG. 7. FIG. 7 is a schematic diagram illustrating a cover 710. In addition to the second pattern layer U2, the second light transmitting ink layer T2, the first light transmitting ink layer T1, the first light transmitting substrate layer S1, the first pattern layer U1, the plating layer N1 and the printing layer N2 similar to those of the cover 610, the cover 710 further includes a second light transmitting substrate layer S2, a third pattern layer U3, a third light transmitting ink layer T3, a fourth light transmitting ink layer T4, a fourth pattern layer U4, and a third light transmitting substrate layer S3.

The third pattern layer U3 and the fourth pattern layer U4 have microstructure patterns. In this embodiment, the second pattern layer U2 and the third pattern layer U3 are attached to the two sides of the second light transmitting substrate layer S2, respectively. The fourth pattern layer U4 is attached to the bottom of the third light transmitting substrate layer S3. The third light transmitting ink layer T3 and the fourth light transmitting ink layer T4 are configured between the third pattern layer U3 and the fourth pattern layer U4 to combine the third pattern layer U3 and the fourth pattern layer U4. The third light transmitting ink layer T3 has a seventh refractive index, and the fourth light transmitting ink layer T4 has an eighth refractive index. The seventh refractive index and the eighth refractive index are different from the fifth refraction index of the first light transmitting ink layer T1 and the sixth refractive index of the second light transmitting ink layer T2. That is, the first light transmitting ink layer T1, the second light transmitting ink layer T2, the third light transmitting ink layer T3, and the fourth light transmitting ink layer T4 have different refractive indices.

Referring to FIG. 7, in this embodiment, the first light transmitting ink layer T1, the second light transmitting ink layer T2, the third light transmitting ink layer T3, and the fourth light transmitting ink layer T4 have different refractive indices. The first pattern layer U1, the second pattern layer U2, the third pattern layer U3 and the fourth pattern layer U4 also have different refractive indices. Consequently, the cover 710 has a rich optical effect.

With the above arrangement, multiple virtual pattern images are presented after light passes through the fourth pattern layer U4, the fourth light transmitting ink layer T4, the third light transmitting ink layer T3, the third pattern layer U3, the second pattern layer U2, the second light transmitting ink layer T2, the first light transmitting ink layer T1 and the first pattern layer U1.

In other embodiments, layers are rearranged, and the number of layers also can be changed to present various virtual pattern images.

Although the present invention has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. An electronic device, comprising:
a cover, including:
a first light transmitting substrate layer; and
a first pattern layer, attached to the first light transmitting substrate layer and including a plurality of first microstructure patterns; and
an outer casing, mounted on the cover, the outer casing includes:
a second light transmitting protection layer, including a first surface facing the cover; and
a second pattern layer, configured at the first surface of the second light transmitting protection layer and including a plurality of second microstructure patterns, wherein the first pattern layer and the second pattern layer are superimposed to form a virtual pattern image.

2. The electronic device according to claim 1, wherein a first distance exists between the first microstructure pattern and the adjacent first microstructure pattern, a second distance exists between the second microstructure pattern and the adjacent second microstructure pattern, and the first distance is different from the second distance.

3. The electronic device according to claim 1, wherein the first pattern layer has a first refractive index, the second pattern layer has a second refractive index, and the first refractive index is different from the second refractive index.

4. The electronic device according to claim 1, wherein the cover further includes:
a first light transmitting protection layer configured above the first light transmitting substrate layer.

5. The electronic device according to the claim 1, wherein the cover further includes:
a second light transmitting substrate layer, configured between the second pattern layer and the first surface of the second light transmitting protection layer, and the second pattern layer is attached to the second light transmitting substrate layer.

6. The electronic device according to the claim 1, wherein the cover further includes:
a plating layer, configured under the first pattern layer; and
a printing layer, configured under the plating layer and having a background color.

7. The electronic device according to the claim 6, wherein the cover further includes:
a base layer, configured under the printing layer.

8. The electronic device according to the claim 1, wherein both types of the first microstructure patterns and the second microstructure patterns are a lenticular type, a micro-lens type, a V-cut type or a Fresnel-lens type.

9. A cover, applied to an electronic device, comprising:
a first light transmitting substrate layer;
a first pattern layer, attached on the first light transmitting substrate layer and including a plurality of first microstructure patterns, wherein the first pattern layer has a first refractive index;
a first light transmitting ink layer, configured above the first pattern layer;
a second pattern layer, attached to a bottom of the first light transmitting substrate layer and including a plurality of second microstructure patterns, wherein the second pattern layer has a second refractive index, and the first refractive index is different from the second refractive index; and
a plating layer, configured under the second pattern layer;
a printing layer, configured under the plating layer and having a background color.

10. The cover according to the claim 9, wherein between the second pattern layer and the plating layer, the cover further includes:
a second light transmitting substrate layer, configured under the second pattern layer;
a third pattern layer, configured between the second pattern layer and the second light transmitting substrate layer, attached to the second light transmitting substrate layer, wherein the third pattern layer has a plurality of third microstructure patterns and a third refractive index, and the third refractive index is different from the first refractive index and the second refractive index; and
a second light transmitting ink layer, configured between the second pattern layer and the third pattern layer.

11. The cover according to the claim 10, wherein between the second light transmitting ink layer and the second light transmitting substrate layer, the cover further includes:
a fourth pattern layer, attached to a bottom of the second light transmitting substrate layer and including a plurality of fourth microstructure patterns, wherein the fourth pattern layer has a fourth refractive index, and the fourth refractive index is different from the first refractive index, and the second refractive index and the third refractive index.

12. The cover according to the claim 10, wherein the first light transmitting ink layer has a fifth refractive index, the second light transmitting ink layer has a sixth refractive index, and the fifth refractive index is different from the sixth refractive index.

13. The cover according to the claim 9, wherein both types of the first microstructure patterns and the second microstructure patterns are a lenticular type, a micro-lens type, a V-cut type or a Fresnel-lens type.

14. A cover, applied to an electronic device, comprising:
a first light transmitting substrate layer;
a first pattern layer, attached on the first light transmitting substrate layer and including a plurality of first microstructure patterns;
a first light transmitting ink layer, configured above the first light transmitting substrate layer and having a fifth refractive index;
a second light transmitting ink layer, configured above the first light transmitting ink layer and having a sixth refractive index, wherein the fifth refractive index is different from the sixth refractive index; and
a second pattern layer, configured above the second light transmitting ink layer and including a plurality of second microstructure patterns.

15. The cover according to the claim 14, further comprising:
a second light transmitting substrate layer, wherein the second pattern layer is attached to the bottom of the second light transmitting substrate layer;
a third pattern layer, attached above the second light transmitting substrate layer; and
a third light transmitting ink layer, configured above the third pattern layer and having a seventh refractive index, wherein the seventh refractive index is different from the fifth refractive index and the sixth refractive index.

16. The cover according to the claim 15, further comprising:
a fourth light transmitting ink layer, configured above the third light-permeable;
a fourth pattern layer, configured above the fourth light transmitting ink layer; and
a third light transmitting substrate layer, wherein the fourth pattern layer is attached to a bottom of the third light transmitting substrate layer.

17. The cover according to the claim 14, wherein both types of the first microstructure patterns and the second microstructure patterns are a lenticular type, a micro-lens type, a V-cut type or a Fresnel-lens type.

18. The cover according to the claim 14, wherein the first pattern layer has a first refractive index, the second pattern layer has a second refractive index, and the first refractive index is different from the second refractive index.
